(19) United States
(12) Patent Application Publication
(10) Pub. No.: US 2008/0277659 A1
(43) Pub. Date: Nov. 13, 2008

(54) Test structure for semiconductor chip

(76) Inventors: Shih-Hsun Hsu, Hsinchu City (TW); Hsien-Wei Chen, Sinying City (TW); Anbiarshy N.F. Wu, Chiayi City (TW)

Correspondence Address: SLATER & MATSIL, L.L.P., 17950 PRESTON ROAD, SUITE 1000, DALLAS, TX, 75252, US

(21) Appl. No.: 11/801,529

(22) Filed: May 10, 2007

(51) Int. Cl. H01L 23/544

(52) U.S. Cl. 257/48; 257/E23.179

(57) ABSTRACT

A test structure for use in a semiconductor chip. In a preferred embodiment, a number of die are formed in an array on a semiconductor wafer substrate. Each die includes an active area defined by a seal ring and is separated from those adjacent to it by a thin scribe line. In addition to the operational structures formed in the active area of each die, one or more test structures are formed. In a preferred embodiment, these test structures are formed into one or more PCM (process control monitor) test pattern layout areas that are positioned near the seal ring and outside of the operational bond pads. Some or all of individual pads in the PCM test pattern layout area may then be connected to corresponding features on adjacent dice, and in some applications enable the simultaneous performance of WAT (wafer acceptance test) and CP (circuit probe) testing.

### TECHNICAL FIELD

The present invention relates generally to the field of semiconductor devices, and relates more particularly to the forming of test structures on semiconductor wafers for the purpose of performing tests such as wafer acceptance test (WATs) and circuit probe (CP) tests on the wafer dice before they are separated into individual chips.

### BACKGROUND

Semiconductor chips are small electronic devices that are used in a wide range of applications such as personal computers, cellular telephones, and gaming devices. Each chip is actually a small piece of semiconductor material onto which have been fabricated a large number of integrated circuits. Each integrated circuit, in turn, includes a number of tiny electronic components that are interconnected together. A semiconductor is a material that when properly prepared is capable of conducting electricity under certain controllable conditions, such as the application of the small electrical charge. Each of the small components in an integrated circuit is fabricated using successive layers of semiconductor, insulating, and conducting materials arranged in a certain fashion. The process of fabricating semiconductor chips will now be briefly reviewed as background for describing the present invention.

The fabrication process begins with providing a substrate of semiconductor material, typically formed in a flat, circular shape called a wafer. Each wafer is cut from an ingot of, for example, silicon, and will be used for the fabrication of a number of semiconductor chips. FIG. 1 is a plan (top) view of a typical wafer 10. As can be seen in FIG. 1, much of the surface 11 of wafer 10 is subdivided into a number of small square or rectangular areas that are at this stage referred to collectively as dice 12. These dice 12 are separated from each other by linear regions formed on surface 11 and sometimes referred to as scribe lines. For purposes of illustration, dice 16 through 19 are enumerated in FIG. 1 and shown as separated from each other by horizontal scribe line 14 and vertical scribe line 15. Note that the selection of these particular features for illustration is arbitrary, and in the example of FIG. 1 the dice and the scribe lines are substantially identical with respect to each other. Eventually, each good die will become a separate semiconductor chip when the fabrication process is complete. (Dice that fail inspection or testing are normally just discarded.) Much of the fabrication process is automated, as great precision is required and the structures being formed on the wafer are very small. A notch 13 formed at the periphery of wafer 10 is in this example used for orientation during fabrication, although other features (not shown) or techniques may be used for this purpose as well.

A number of steps are involved in fabricating the individual structures used to create the electronic components that will form integrated circuits. These will not be described in detail here, although in general they involve the deposition of various layers of material that may selectively be removed, for example by chemical etching, to create the necessary structures. For example, a transistor (not shown) is basically formed of a gate structure that includes an electrode of crystalline polysilicon that is separated from the wafer substrate by a thin layer of dielectric material. A source region formed in the substrate on one side of the gate structure and a drain region formed on the other define a channel through which electrical current may flow when a small voltage is applied to the gate structure. The source region and the drain region are formed by selectively doping appropriate portions of the wafer surface. Doping involves treating the selected substrate portions with, for example, ionized boron or phosphorous.

The selective deposition, etching, and doping are frequently achieved by first building protective structures on portions of the surface that are intended to remain unaffected by the process involved. These protective structures may be created using a process called photolithography. In photolithography, a material called photoresist is applied to the surface of the wafer, and then selectively developed by exposing certain areas of the photoresist to light energy. This exposure causes the selected areas to become either more or less resistant (depending on the type of photo resist used) to a selected solvent that is then used to remove all the desired protective structures. After the actual deposition, etching, or doping process is performed, the remaining photoresist structures are removed using a different solvent.

When fabrication is complete, or nearly so, the individual dice may be separated using one of several methods that are sometimes referred to as singulation, or dicing. As should be apparent, singulation is effected by cutting or breaking the wafer apart including, for example, at the pre-formed scribe lines 14 and 15 that are visible in FIG. 1. These scribe lines are shown more clearly in FIG. 2. FIG. 2 is a top view illustrating a portion 10′ of the semiconductor wafer 10 shown in FIG. 1. The scribe lines are, basically, regions disposed between each of the dice. As used herein, a scribe line may simply be the space in between two dice, or may also include a recess formed in the surface of the wafer substrate. In FIG. 2, it may be seen that each die includes an active area, for example active area 26 shown on die 16. Simply stated, the active area is a portion of the wafer on which the operational electrical components are to be formed. A seal ring is typically formed around the periphery of the active area to protect the electrical components, for example, during the singulation process.

In the example of FIG. 2, for example, seal rings that are about 16 μm in thickness surround each of the active areas depicted, with seal rings 31 through 34 surrounding each of respective active areas 26 through 29. This configuration would, of course, be typical for each of the active areas present in the wafer 10 in most applications. Note that the seal rings shown in FIG. 2 are continuous about their respective active area, although this is not necessarily the case. Note also that the FIG. 2, as with the rest of the Drawings in this disclosure, is not necessarily drawn to scale.

As mentioned above, semiconductor chips are tested, both after they are completed and at various points during the fabrication process. This testing may take a number of forms. WAT (wafer acceptance testing) involves using PCMs (process control monitors) to conduct a number of tests using statistical methods to analyze the success of the wafer fabrication process and attempt to determine the cause of any fabrication deficiencies. Another test referred to as a CP (circuit probe) test involves using one or more probes to determine which die are good and which are not. To facilitate these tests, test structures are provided. These test structures typically include probe pads located in the scribe line area, for example probe pads 22 shown in FIG. 2. Also shown in FIG. 2 are PCM test pattern layout areas 20, which are pad arrays used for various testing functions. Although each of PCM test pattern layout areas 20 is shown here to have five pads, there could be as many as the particular structure is able to accommodate. As should be apparent, the test structures shown are only the visible portion of the test structure, which would normally include one or more underlying metal layers (not shown) that are used to connect the pad at the surface with operational components in the chip's active area. Note that is used herein, the term “test structure” is used to refer to electrical components that are used solely for testing in connection with the fabrication process. Other “operational structures” may of course be used for testing as well, but are also necessary or desirable for operation of the finished device. The distinction, therefore, is that test structures may be sacrificed or discarded after or at some point during fabrication. The test structures located in the scribe lines, for example, will be destroyed during the singulation process.

After singulation, each individual chip may then be mounted in some form of package (not shown) that provides physical and electrical protection. During the mounting process, wires, leads, or conductive bumps may be used to provide external electrical connections. The chip, and sometimes multiple chips, may for example be encased in a hard plastic material referred to as an encapsulant. The packaged chips may then be installed on a printed wire board or similar structure for mounting in a particular electrical appliance.

In some applications, the singulation process is achieved by a saw that is used to cut completely through the semiconductor wafer along each of the scribe lines. In other cases, saws form kerfs part way through the wafer in one or more locations on or near the scribe lines, and an impact tool is then used to break apart the dice along the kerfs. In either scenario, the presence in the scribe lines of the relatively large amounts of metal associated with the PCM test structures may lead to excessive damage to surrounding materials during the sawing or dicing processes.

Needed, therefore, is a way to permit the efficient separation of the wafer into individual dice, all at the same time permitting the use of narrower scribe lines. The present invention provides just such a solution.

### SUMMARY OF THE INVENTION

These and other problems are generally solved or circumvented, and technical advantages are generally achieved, by preferred embodiments of the present invention which are directed to a semiconductor chip fabricated with test structures, for example a plurality of PCM test pattern layouts, formed in the active area defined by the seal ring.

In accordance with a preferred embodiment of the present invention, a semiconductor chip includes an active area formed on a semiconductor substrate and surrounded by a seal ring, and at least one test structure formed in the active area. Preferably, the at least one test structure includes a plurality of test structures organized into PCM test pattern layout arrays located near the periphery of the chip between most of the operational structures on the chip and the seal ring. The seal ring itself has a width w_{SR} of between about 1 and 10 μm and preferably about 5 μm, in which case the PCM test pattern layout area may have a width w_{PCM} between about 20 and 50 μm. A semiconductor chip is preferably formed as a die on a semiconductor wafer that is separated from other, adjacent dice by a scribe line having a width W_{SL}.

In another aspect, the present invention is a method for testing a semiconductor device including forming an active area having operational devices on a substrate, forming a seal ring, and preferably a continuous seal ring on the semiconductor-device surface about the periphery of the active area, forming at least one test structure on the active area inside the seal ring, and using the at least one test structure to perform a WAT (wafer acceptance test) or a CP (circuit probe) test, or both. In one embodiment, the WAT and CP test are performed simultaneously.

In yet another aspect, the present invention is a method of fabricating a semiconductor device including providing a semiconductor substrate, forming at least one die on the substrate, the die having an active area surrounded by a seal ring of about in a range of 1 to 10 μm in width and separated from any adjacent dice by a scribe line no more than about 10 μm in width and preferably having within it no test structures. Instead, at least one test structure is formed in the active area and certain tests performed. After testing, the dice are separated and packed for use.

An advantage of a preferred embodiment of the present invention is that narrower scribe lines may be used between dice, and as a consequence more dice may be fabricated on the semiconductor wafer.

A further advantage of a preferred embodiment of the present invention is that by eliminating or reducing the metal materials used to make the test structures from the scribe lines, dicing may be performed by laser cutting or etching and cause less damage to the dice adjacent to the scribe line.

As more complete appreciation of the present invention and the scope thereof can be obtained from the accompanying drawings that are briefly summarized below, the following detailed description of the presently-preferred embodiments of the present invention, and the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a plan (top) view of a typical semiconductor wafer.

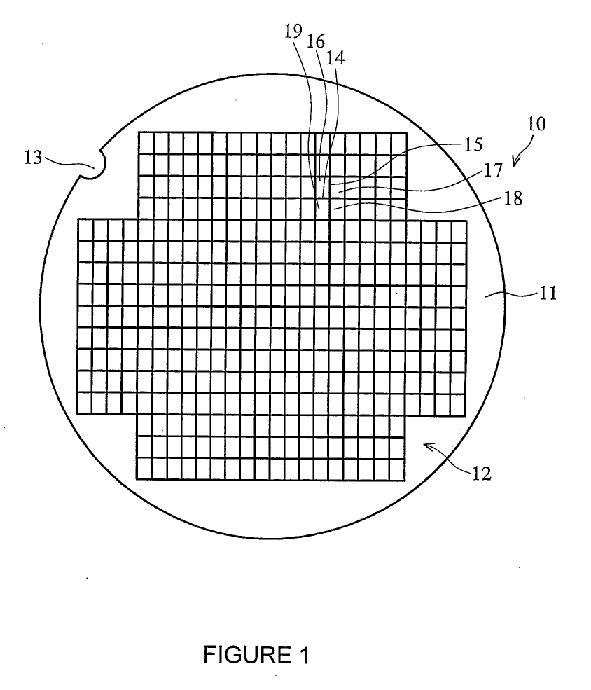

FIG. 2 is a top view illustrating a portion of the semiconductor wafer shown in FIG. 1.

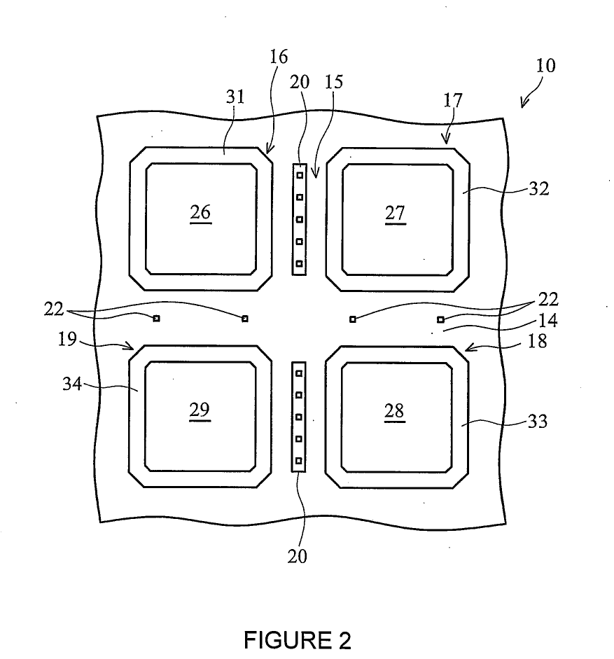

FIG. 3 is a top view of a portion of a semiconductor wafer fabricated according to an embodiment of the present invention.

FIG. 4 is a plan view of one of the four dice illustrated in FIG. 3.

FIG. 5 is a flow diagram illustrating a method of testing a semiconductor device according to an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a semiconductor wafer having formed upon it a number of identical dice that are separated by scribe lines, where all of the testing structures associated with the wafer and each of the dice thereon have been formed in test pattern layout areas within the active area of each die, which is surrounded by a continuous seal ring. The present invention may also be applied, however, to other semiconductor devices as well, such as those with multiple types of testing structures.

As mentioned above, although some operational structures may be used for testing purposes, it is imperative for modern semiconductor device fabrication processes that test structures dedicated solely to the testing function also be formed. Some or all of these testing structures are commonly referred to as PCMs (process control monitors). Forming these PCM testing structures within the scribe line region, however, increases the likelihood that damage will occur to the operational areas of one or more chips during the singulation process. It also, in effect, limits the width to which the scribe line may be narrowed. This in turn may limit the number of chips that may be formed from a given wafer. The present invention provides a solution to this dilemma by providing testing structures within the active area without reducing the amount of active area usable for operational structures.

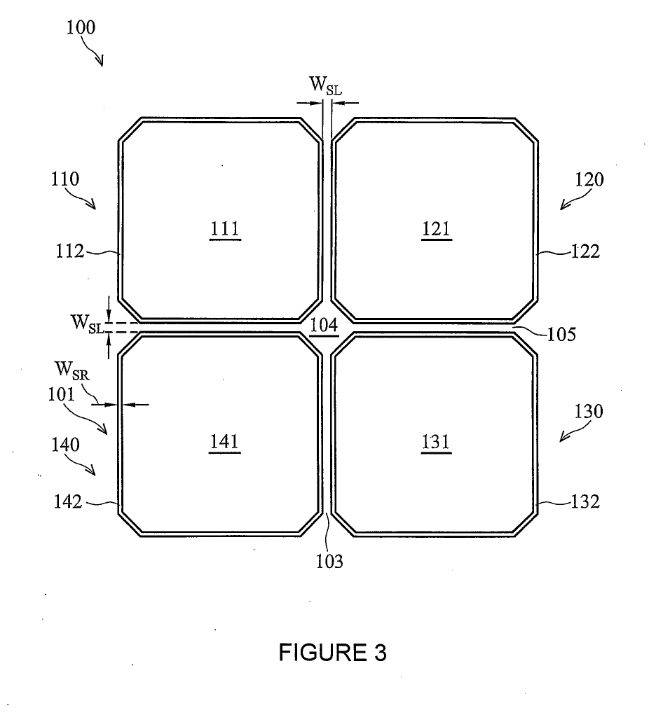

FIG. 3 is a top view of a portion 100 of a semiconductor wafer fabricated according to an embodiment of the present invention. Four dice, numbered 110, 120, 130, and 140 are illustrated in this Figure. Each die has an active area, numbered 111, 121, 131, and 141, respectively, in which are fabricated the operational structures organized into integrated circuits that give the finished chip its functionality. In this embodiment, each of these active areas is surrounded by a respective seal ring 112, 122, 132, or 142. Each seal ring in this embodiment has a width W_{SR} of in the range of about 1 to 10 μm, preferably about 5 μm. Dice 110 and 140 are separated from dice 120 and 130 by scribe line 103, and dice 110 and 120 are separated from dice 130 and 140 by a scribe line 105, which intersects scribe line 103 at intersection 104. As FIG. 3 shows only a portion of semiconductor wafer 100, there are of course other scribe lines lying outside of the four dice depicted although they are not separately numbered. In this embodiment, scribe lines 103 and 105 both have a width w_{SL} of in the range of about 1 to 10 μm, preferably about 5 μm. In this embodiment, the other scribe lines (not shown) on the semiconductor wafer also have a width W_{SL}. Note that while the uniformity in widths shown in FIG. 3 is not unexpected, it is also not required. Horizontal scribe lines may, in an alternate embodiment (not shown), be wider or narrower than vertical scribe lines.

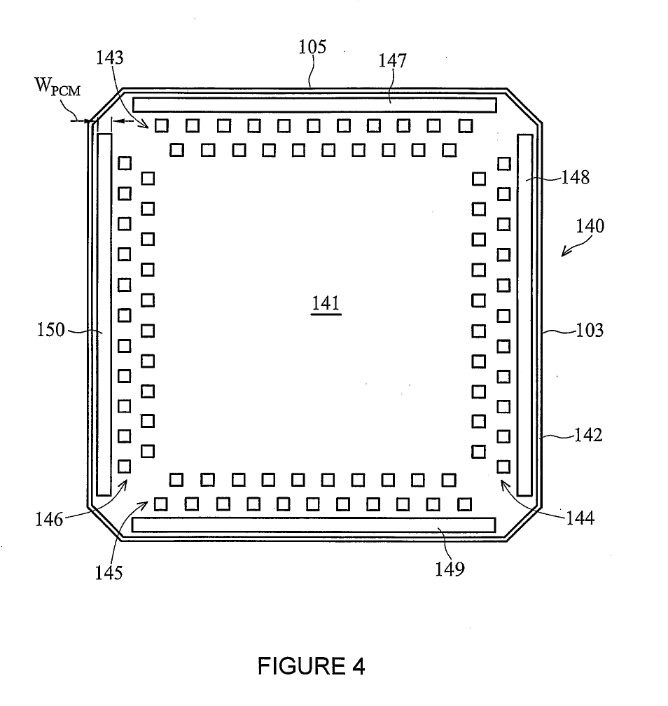

FIG. 4 is a plan view of the die 140, one of the four dice illustrated in FIG. 3. In FIG. 4, bond pads are visible in four separate arrays 143, 144, 145, and 146 surrounding active area 141. These bond pads are typically, though not necessarily, operational structures. Some may, however, be used for testing purposes. In this embodiment, between each array of bond pads and seal ring 142 is a PCM test pattern layout area. PCM test pattern layout area 147, for example, is disposed between bond pad array 143 and the seal ring 142. In this embodiment, PCM test pattern layout area 147 has a width w_{PCM} of in the range of about 20 to 50 μm, preferably about 30 μm, as do PCM test pattern layout areas 148, 149, and 150. Note that as used herein, a PCM test pattern layout area may include one or more test structures, including pad areas (not shown) accessible from the surface 101 of wafer portion 100. The layout of the actual structures within the PCM test layout areas may vary considerably without detracting from the advantages of the present invention. Note also that this location of the PCM test pattern layout areas shown in FIG. 4 is exemplary. Locating the PCM areas as shown in FIG. 4 will in some embodiments, however, enable the efficient connection of one PCM test structure to another. In addition, the WAT and CP tests may be performed simultaneously in some applications.

Note that in the embodiment of the present invention described above, situating the PCM within the active area 141, that is, within the area defined by the seal ring 142, does not affect negatively the amount of chip surface area that may be used for the fabrication of operational devices. This is due to the fact that the area taken up by the PCM is less than that recovered by narrowing the seal ring and, especially, the scribe lines. The reduction of these features is, of course, made possible by the present invention, where moving the PCM structures out of the scribe line allows it to be made narrower, and reduces the need for a more substantial seal ring. In fact, dicing in the traditional sense may be unnecessary, with separation of each individual die achievable instead by a laser or an etch process.

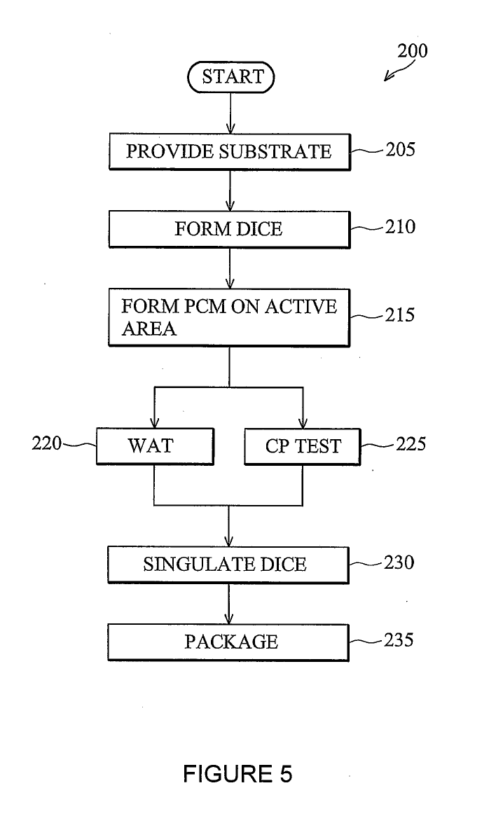

In another embodiment, the present invention is a semiconductor-device testing method. FIG. 5 is a flow diagram illustrating a method 200 of testing a semiconductor device according to an embodiment of the present invention. In this embodiment, method 200 includes providing a semiconductor wafer substrate (step 205), forming an array of dice on the substrate (step 210), each die separated from adjacent dice by a scribe line and having an active area surrounded in whole or in part by a seal ring, forming at least one PCM test structure within the active area of at least one die (step 215), and performing a WAT using the at least one PCM test structure (step 220). In a preferred embodiment, a CP test is also performed (step 225) at the same time as the WAT. In an alternate embodiment (not shown), the WAT and the CP test are performed in sequence instead of simultaneously. In another alternate embodiment (also not shown), only the CP test is performed and the WAT is omitted. In the embodiment of FIG. 5, after testing, the dice are singulated (step 230) into individual chips. This is preferably achieved by using a laser cutting tool or an etching process. Each die identified as a good die in the fabrication testing process is packaged (step 235) for individual use. Note that the steps of method 200 may be performed in any logically-permissible order unless explicitly recited otherwise in a claim, and other operations may be inserted in the sequence of method 200 without departing from the spirit of the invention.

Although the present invention and its advantages have been described in detail, it should be understood that various changes, substitutions and alterations can be made herein without departing from the spirit and scope of the invention as defined by the appended claims. For example, symmetry of layout is not required, and the measurements recited above are intended to be exemplary rather then limiting.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor chip, comprising:
a substrate comprising an active area;
a seal ring disposed at the surface of the substrate, the seal ring substantially surrounding the active area; and
at least one PCM (process control monitor) test structure, wherein the at least one PCM test structure is disposed entirely within the seal ring.

2. The semiconductor chip of claim 1, wherein the at least one PCM test structure is disposed at the periphery of the active area.

3. The semiconductor chip of claim 2, further comprising an array of bond pads, and wherein the PCM test structure is disposed between the array of bond pads and the seal ring.

4. The semiconductor chip of claim 1, wherein the at least one PCM test structure comprises a plurality of test structures.

5. The semiconductor chip of claim 1, wherein the PCM test structure is operable to enable a WAT (wafer acceptance test).

6. The semiconductor chip of claim 5, wherein the PCM test structure is operable to enable a CP (circuit probe) test.

7. The semiconductor chip of claim 1, wherein the at least one PCM test structure is disposed within an area that is substantially an elongated rectangle in shape.

8. The semiconductor chip of claim 7, wherein the elongated rectangle defining the PCM test structure is less than or equal to about 50 μm in width.

9. The semiconductor chip of claim 1, wherein the seal ring is less than about 10 μm in width.

10. The semiconductor chip of claim 1, wherein the seal ring is continuous about the active area periphery.

11. A semiconductor wafer, comprising:
a plurality of integrally-formed dice arranged in a planar array and separated from each other by scribe lines formed between them;
wherein each die of the plurality of dice includes a seal ring defining an active area, and wherein each active area includes at least one PCM pattern layout area.

12. The semiconductor wafer of claim 11, wherein the active area further includes a plurality of operational bond pads.

13. The semiconductor wafer of claim 12, wherein the at least one PCM test pattern layout area is disposed between the plurality of operational bond pads and at least a portion of the seal ring.

14. The semiconductor wafer of claim 11, wherein the scribe lines are less than or equal to about 10 μm in width.

15. The semiconductor wafer of claim 11, wherein the seal ring defining each active area completely surrounds each active area.

16. The semiconductor wafer of claim 15, wherein each seal ring is less than or equal to about 10 μm in width.

17. The semiconductor wafer of claim 11, wherein the PCM test patterns of one die is connectable to the PCM test pattern layout of an adjacent die.

18. The semiconductor wafer of claim 11, wherein the PCM test pattern is less than or equal to about 50 μm in width.

19. The semiconductor wafer of claim 11, wherein the plurality of dice comprises all of the dice on the semiconductor wafer.

20. A semiconductor device, comprising at least one PCM test structure about 30 μm in width, and disposed within a seal ring about 5 μm in width, the seal ring formed on the surface of a semiconductor substrate and surrounding an active area formed on the substrate.
